(19) United States
(12) Patent Application Publication
(10) Pub. No.: US 2006/0001162 A1
(43) Pub. Date: Jan. 5, 2006

(54) Nitride and polysilicon interface with titanium layer

(76) Inventors: Ronald J. Schutz, Dresden (DE); Werner Robl, Regensburg (DE); Rajeev Malik, Pleasantville, NY (US); Lawrence A. Clevenger, Lagrangeville, NY (US); Oleg Gluschenkov, Poughkeepsie, NY (US); Cyril Cabral JR., Mahopac, NY (US); Roy C. Iggulden, Stoughton, MA (US); Yun-Yu Wang, Poughquag, NY (US); Keith Kwong Hon Wong, Wappingers Falls, NY (US); Irene Lennox McStay, Hopewell Junction, NY (US)

Correspondence Address: SLATER & MATSIL LLP, 17950 PRESTON ROAD, SUITE 1000, DALLAS, TX, 75252, US

(21) Appl. No.: 11/084,724

(22) Filed: Mar. 18, 2005

Related U.S. Application Data
(63) Continuation of application No. PCT/US03/29085, filed on Sep. 16, 2003.
(60) Provisional application No. 60/411,710, filed on Sep. 18, 2002.

(51) Int. Cl. H01L 23/48; H01L 21/4763

(52) U.S. Cl. 257/754; 438/630; 257/761; 438/648

(57) ABSTRACT

A conductive structure in an integrated circuit (12), and a method of forming the structure, is provided that includes a polysilicon layer (30), a thin layer containing titanium over the polysilicon, a tungsten nitride layer (34) over the titanium-containing layer and a tungsten layer over the tungsten nitride layer. The structure also includes a silicon nitride interfacial region (38) between the polysilicon layer and the titanium-containing layer. The structure withstands high-temperature processing without substantial formation of metal silicides in the polysilicon layer (30) and the tungsten layer (32), and provides low interface resistance between the tungsten layer and the polysilicon layer.

This application is a continuation of co-pending International Application No. PCT/US2003/029085, filed Sep. 16, 2003, which designated the United States and was published in English, and which claims priority to U.S. Provisional Patent Application No. 60/411,710, filed Sep. 18, 2002, both of which applications are incorporated herein by reference.

### TECHNICAL FIELD

The present invention relates to conductive structures used in semiconductor devices and to methods of manufacturing the same.

### BACKGROUND

Polycrystalline silicon or “polysilicon” structures are commonly used as conductive elements in integrated circuits.

For example, in memories and other devices, an oxide-insulating layer overlies the channel region of a field effect transistor (“FET”) and a conductive polysilicon layer overlying the oxide layer serves as the gate of the FET. The amount of electrical charge on the gate controls the conductivity through the channel region of the FET. Thus, the speed at which the transistor can be switched from a conducting state to a nonconducting state or vice-versa is directly related to the speed with which charge can be delivered to or removed from the gate.

In many integrated circuits, the conductive structure that forms the gate also serves as an elongated conductor extending within the integrated circuit. For example, an elongated strip of conductive material may serve as the gate of numerous FETs. Such a strip is connected to another element of the integrated circuit that supplies charge. For a given strip geometry, the speed with which charge can be delivered to that portion of the strip forming the gate of an FET remote from the charge source is limited by the electrical resistance of the strip.

Polysilicon has relatively high resistivity. Therefore, a strip or other elongated feature formed entirely from a thin layer of polysilicon having a small cross-sectional area will have a relatively high resistance. To provide lower resistance in a comparable cross-sectional area, conductive features have been fabricated heretofore using a layer of polysilicon with an additional layer of a highly conductive material such as elemental metals (e.g., tungsten W, molybdenum Mo, tantalum Ta, Niobium Nb, Rhenium Re, Iridium Ir, Hafnium Hf, Cobalt Co, Nickel Ni) or metallic compounds such as metal silicides (e.g., tungsten silicide WSi_{X}, titanium silicide TiSi_{X}, cobalt silicide CoSiₓ, nickel silicide NiSiₓ) or metal nitrides (e.g., titanium nitride TiN_{X}, tungsten nitride WN_{X}, tantalum nitride TaNₓ), overlying the polysilicon layer. The elemental metals typically have a lower resistivity than respective metallic compounds and, therefore, are highly preferred.

Accordingly, in some useful applications of low resistance gate structures, highly conductive elemental metal conductors are formed atop a higher-resistance silicon-containing material such as polycrystalline silicon, polycrystalline silicon-germanium, and/or metal silicides (e.g., WSi, CoSi, NiSi). However, such composite features with elemental metal conductors are susceptible to unintended formation of metal suicides from the metals in the elemental metal conductors. Such silicides can form, for example, when an integrated circuit incorporating the elemental metal and adjacent silicon-containing conductive element is subjected to high temperature processing operation for fabrication of additional structures after deposition of the composite conductive element. Conversion of the metal to the metal silicide is undesirable because it raises the resistance of the composite structure.

Formation of metal silicides can be substantially suppressed by depositing a barrier layer rich in nitrogen between the metal layer and the silicon-containing layer. For example, one structure for a conductive element includes a layer of polysilicon with a layer of tungsten nitride WNₓ or tungsten silicon nitride WSiₓN_{y} overlying the polysilicon and with a layer of metallic tungsten overlying the nitride-based silicidation barrier. The subscripts x and y refer to relative mole fractions. In another example, a typical contact structure includes a titanium nitride TiNₓ or tantalum nitride TaNₓ barrier between an elemental tungsten W contact plug and a silicon-containing conductive element such as doped silicon and/or metal silicide (e.g., WSi, CoSi, NiSi) yielding the following stacks W/TiN/Si, W/TiN/WSi, W/TiN/CoSi, W/TiN/NiSi or the corresponding tantalum nitride stacks. In yet another example, Clevenger, et al. (U.S. Pat. No. 6,444,516) discloses a conductive gate structure where a silicidation barrier includes silicon oxide (SiO₂), silicon nitride (SiNₓ) or silicon oxynitride (SiNₓO_{y}) between an elemental tungsten layer and a conductive polysilicon layer. These structures are referred to, hereinafter collectively, for convenience as W/SiON/polySi structures, where SiON refers to any of the barrier layers disclosed in U.S. Pat. No. 6,444,516, which is hereinafter incorporated by reference in its entirety.

However, each of these three examples suffers from some limitations:

1. W/TiN/Si, W/TiN/WSi, W/TiN/CoSi, W/TiN/NiSi or respective tantalum nitride structures cannot be used at temperatures typically used in or after gate conductor processing (e.g., at about 900° C. or above), and cannot be exposed to an oxidizing environment, which is typically required during processing in the formation of gate conductors.

2. WN or WSiN can react with polysilicon during or after deposition forming a thick semi-insulating barrier leading to higher interface resistance (contact resistance) between the metal and the underlying polysilicon gate. For example, when such structures are subjected to high temperature processing as, for example, at about 1,000° C., a nitrogen rich interfacial region containing silicon-nitrogen compounds such as silicon nitride develops in that portion of the polysilicon layer abutting the tungsten nitride layer. Without being limited by any theory of operation, it is believed that the silicon-nitrogen semi-insulating compounds form a barrier to diffusion of tungsten from the tungsten and tungsten nitride layers into the polysilicon layer, or of silicon from the polysilicon layer into the tungsten layer, which, in turn, substantially prevents formation of tungsten silicide. In addition, it is believed that during the deposition of WN, the reactive nitrogen (N) plasma used in the deposition process reacts with native silicon oxide that is formed on the surface of the polysilicon and with the polysilicon to form a thick semi-insulating barrier. A W/WSiN/polySi stack would also develop a higher resistance semi-insulating layer after the high temperature gate stack processing. Thus, typical composite conductive structures such as W/WN/polySi after high temperature treatment have a relatively high interface resistance between the tungsten layer and the polysilicon layer. For example, typical structures of this type have an interface resistance of about 5,000-10,000 Ω-μm². Although the overall sheet resistance of this structure is lower than that of WSi_{X}, the SiON layer results in relatively higher contact resistance for the stack than for a stack comprising W/WSiₓ/polySi. This leads to reduced speed of charging/discharging of the gate electrode and, consequently, to degraded performance of high-speed circuits.

3. The electrical conductivity of the SiON barrier disclosed in U.S. Pat. No. 6,444,516 increases as the thickness of the barrier decreases, but if the barrier is too thin, the thermal stability of the structure can be adversely affected. For typical gate applications, the minimal thermal stability requirement is driven by junction activation anneals and several thermal oxidation steps such as gate sidewall oxidation. Accordingly, the gate structure should be able to withstand at least 950° C., 30 sec. anneals, and, preferably, up to 1000° C., for 30 sec. The capacitive coupling mechanism disclosed in U.S. Pat. No. 6,444,516 allows for a reduction of the conductivity requirement of the semi-insulating barrier but is not suitable for certain high-speed circuits and/or signals. For instance, a chain of high-speed inverters using the capacitive coupling mechanism would substantially alter a single pulse signal propagation because each inverter gate has a built-in high-pass capacitive filter. Such a capacitive high-pass filter cuts a low frequency component of the applied signal at each stage. For a single pulse signal, this filter effect leads to a narrower and smaller pulse at the output of each inverter. Therefore, a short single pulse signal can be completely lost after passing through a large chain of such inverters where each inverter has a capacitively coupled gate conductor and gate electrode. Therefore, the charging of gate electrode using a pure capacitive coupling mechanism is not suitable for many digital circuits.

Accordingly, further improvement would be desirable. It would be desirable to provide a conductive element having the desirable properties of structures such as W/WN/polySi including the ability to withstand high temperature processing during manufacturing operations, but also having lower interface resistance. It would also be desirable to provide methods of manufacturing such as conductive structures and integrated circuits incorporating such conductive elements.

### SUMMARY OF THE INVENTION

One aspect of the present invention provides a method of forming a conductive structure including the steps of depositing a layer including a metal, referred to herein as an “interface metal” over a silicon-containing layer such as polysilicon, depositing a layer including a metal nitride over the interface metal and depositing a layer including a further metal, referred to herein as a “conductor metal” over the nitride. The interface metal preferably is a metal, which is highly reactive with nitrogen, and which forms an electrically conductive nitride. Titanium is particularly preferred as the interface metal. The layer including the interface metal, as deposited, desirably is relatively poor in nitrogen. That is, the interface metal is not substantially in the form of a nitride as deposited. The conductor metal desirably is selected to withstand high temperature processing, tungsten being particularly preferred in this regard. For process simplicity, the metal nitride optionally may be the nitride of the conductor metal or the nitride of the interface metal. In a particularly preferred method, the layer including the interface metal consists essentially of titanium, the layer including the conductive metal nitride consists essentially of tungsten nitride and the conductor metal layer consists essentially of tungsten. The interface metal layer desirably is about 10 nm (100 Å) thick or less, more preferably about 0.25 to 2.5 nm, and most preferably 0.5 nm to about 1 nm thick. The thickness referred to is the average thickness of the layer. The most preferred interface metal layer thickness corresponds to about a single atomic layer. The interface metal layer need not be of uniform thickness or continuous; it may be deposited as islands of interface metal on the underlying silicon-containing layer, which desirably conform to a discontinuity criterion defined below. The interface metal layer thickness may be deduced from a known rate of interface metal deposition in a process such as sputtering and the duration of the deposition process or may be determined by measuring the interface metal average surface atom density (e.g., using a Total reflection X-ray Fluorescence (TXRF) technique), or, alternatively, via the measurement of optical reflectivity in the Ultraviolet (UV) region of the spectrum.

The method most desirably includes the step of processing the structure at an elevated temperature, above about 800° C. and most typically about 1,000° C., after deposition of the layers mentioned above.

The deposited structure is substantially resistant to formation of metal silicides during the high temperature processing step and during service. However, the structure, after high temperature processing, has an interface resistance substantially lower than a comparable structure with a metal nitride layer but without the interface metal. Thus, structures in accordance with preferred embodiments of the present invention, with the interface metal, desirably have interface resistance below 500 Ω-μm² and most typically below about 200 Ω-μm² after high-temperature processing. The most preferred structures have an interface resistance on the order of 70-80 Ω-μm². Although the present invention is not limited by any theory of operation, it is believed that the interface metal reacts with some of the nitrogen diffusing from the metal nitride layer into the polysilicon layer during high temperature processing and, thus, limits the amount of silicon-nitrogen compounds formed in the interfacial region of the polysilicon layer. It is believed that this, in turn, leads to a lower interface resistance than would occur in the absence of the interface metal. However, it is also believed that the interface metal does not form a complete barrier to diffusion of nitrogen into the polysilicon layer, and that some silicon-nitrogen compounds form in the interfacial region of the polysilicon layer and serve as a barrier to diffusion of metal into the silicon-containing layer or diffusion of silicon into the metal layer.

A further aspect of the invention provides conductive structures for incorporation in a monolithic microelectronic device. A conductive structure according to this aspect of the invention includes a silicon-containing layer such as polysilicon, an interface metal layer including an interface metal over the polysilicon layer and a metal nitride over the interface metal layer, together with a layer of a conductor metal over the metal nitride layer. As discussed above in connection with the methods, the interface metal desirably is a metal that is highly reactive with nitrogen at elevated temperatures to form a conductive metal nitride and most preferably the interface metal is titanium. In the completed structure, after high-temperature processing, the interface metal may be present in whole or in part as the metal nitride. The silicon-containing layer desirably includes an interfacial region as discussed above adjacent the interface metal layer, where the interfacial region is preferably less than about 15 Å, more preferably between about 5 Å and about 10 Å. This interfacial region is enriched in nitrogen relative to the remainder of the silicon-containing layer and typically contains nitrogen in the form of silicon-nitrogen compounds such as silicon nitride. Conductive structures according to this aspect of the invention may be formed, for example, by the methods discussed above. Here again, the metal nitride layer desirably is the nitride of the conductor metal, and the most desirable conductor metal is tungsten.

Desirably, the metal nitride layer is about 1-24 nm (10-240 Å) thick and preferably about 4 nm to about 16 nm thick, and most desirably about 4 nm to about 10 nm thick, although thicker nitride layers can be used. The relatively thick nitride layer tends to provide a fine grained structure at the surface remote from the interface metal layer and the silicon-containing layer, which, in turn, favors the growth of relatively large grains in the conductor metal. This, in turn, enhances conductivity of the conductor metal and, hence, conductivity of the entire structure.

### DESCRIPTION OF THE DRAWINGS

For a more complete understanding of the present invention, and the advantages therefor reference is now made to the following descriptions taken in conjunction with the accompanying drawings, in which:

FIG. 1 is a fragmentary, diagrammatic sectional view of an integrated circuit in accordance with one embodiment of the invention;

FIG. 2 is a fragmentary diagrammatic view on an enlarged scale of the area indicated in FIG. 1;

FIG. 3 is a fragmentary view taken along line 3-3 in FIG. 1;

FIG. 4 is an EELS spectrum of a semiconductor structure formed in accordance with one embodiment of the present invention;

FIG. 5 is a set of SEM images, which illustrate barrier stability test results; and

FIG. 6 is a further set of SEM images, which illustrate barrier stability test results.

### DETAILED DESCRIPTION OF ILLUSTRATIVE EMBODIMENTS

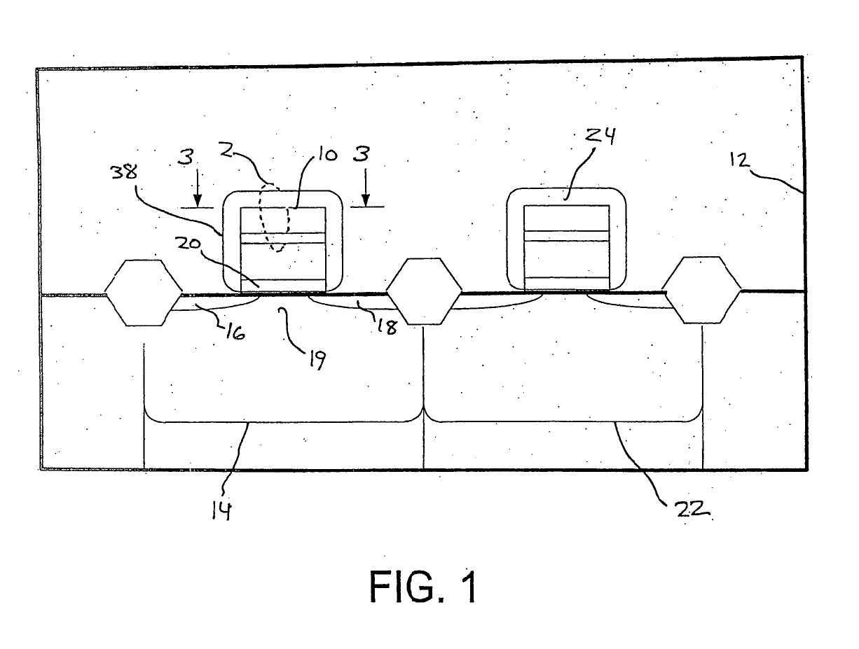

As depicted in FIG. 1, a conductive structure 10 according to one embodiment of the invention may be incorporated in an integrated circuit. Such a device may include large numbers of electronic elements in a unitary structure such as a chip or wafer. A small fragment of the unitary structure 12 is shown in FIG. 1. In the depicted structure, the conductive element 10 serves as the gate of a field effect transistor or FET 14. The FET includes a pair of n⁺-doped silicon regions 16 and 18, which serve as the source and drain of the FET, and a p-doped region 19 forming the channel. Conductive structure 10 is separated from the channel region 19 by an insulating layer 20. FET 14 may be part of a CMOS structure including a further FET 22 having opposite doping and associated with a further conductive element 24.

The gate insulator layer 20 can include various insulating materials such as silicon oxide, silicon oxynitride, silicon nitride, and so-called “high-k” insulators with dielectric permittivity k higher than that of silicon nitride. Examples of high-k insulating materials include hafnium-based insulating compounds such as HfO₂, HfOₓN_{y}, and HfSiₓO_{y}N_{z}, aluminum-based insulating compounds such as oxide Al₂O₃ and AlOₓN_{y}, and titanium-based compounds such as TiOₓ, TiOₓN_{y}, and TiSiₓO_{y}N_{z}. Furthermore, the gate insulator 20 may include isolated semiconductor material such as floating gates and floating nano-particles and charged interfaces such as silicon oxide-silicon nitride interfaces, which typically would be used where the structure is employed in a nonvolatile electrically programmable memory.

The unitary structure 12, including FETs 14 and 22 are built in a semiconductor substrate. The semiconductor substrate may comprise any semiconducting material including Si, SiGe, SiC, SiGeC, GaAs, InAs, InP or other III/V compound semiconductors. The semiconductor substrate may also comprise a multilayer structure in which at least the top layer is semiconducting. Examples of multilayer structures include Si/SiGe, a silicon-on-insulator (SOI), and a SiGe-on-insulator (SGOI). The semiconductor substrate may also be comprised of various useful structures such as memory cells, isolation structures (e.g., isolation trenches), dopant wells, three dimensional transistor features such as fins and pillars, and buried contacts and interconnects.

In the case of three-dimensional FETs, the gate insulator 20 and associated transistor channel region 19 can be oriented at an angle to the substrate surface and/or outer surface of conductive element 10. An illustrative example of a three-dimensional FET is a vertical FET formed on the walls of a trench. In the case of the vertical FET, the transistor channel region 19 is oriented vertically or perpendicular to the substrate surface with one of the doped regions 16 being below the channel region 19 and the other doped region 18 being above the channel region 19. In this case, the conductive element 10 may be comprised of a vertically elongated portion to form a vertical gate and a horizontally elongated portion to form a local interconnect. The particular integrated circuit structure shown is depicted for illustrative purposes only; the same conductive elements can be used in other structures.

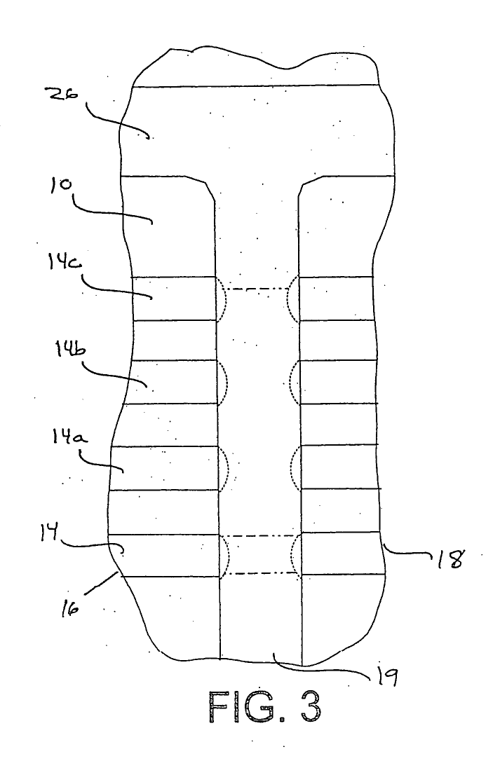

As best appreciated with reference to FIG. 3, conductive element 10 is a horizontally elongated element and interacts with numerous additional FET structures 14a, 14b, 14c, in addition to the particular FET structure shown in FIG. 1. Conductive element 10 is connected to a further structure such as a driving CMOS inverter circuit element or other source of charge (not shown) through a bus 26. Conductive element 24 (FIG. 1) has a similar layout. The particular integrated circuit structure shown is depicted for illustrative purposes only; the same conductive elements can be used in other structures.

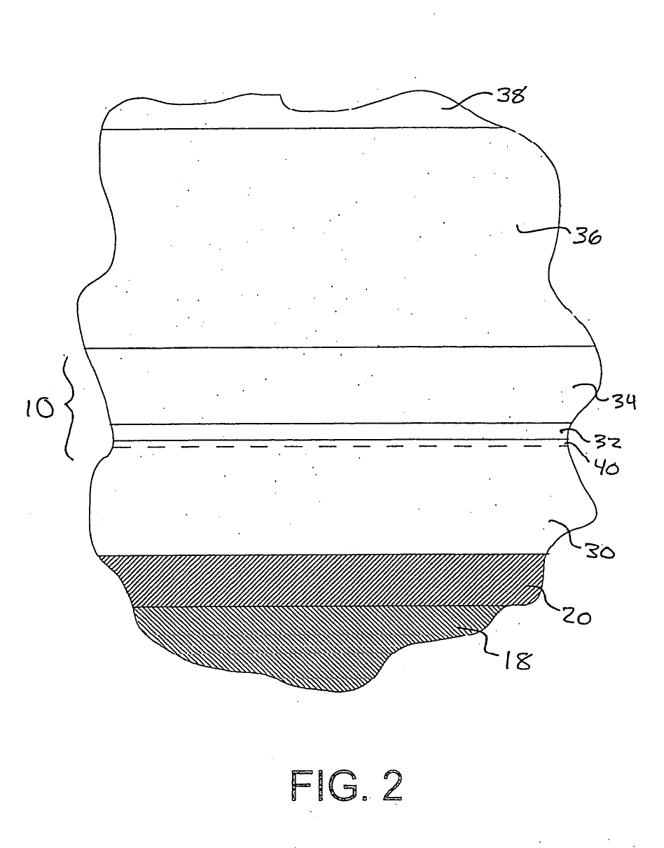

As best seen in FIG. 2, conductive element 10 includes a silicon-containing electrically conductive layer 30, which in this embodiment is a polysilicon layer; an interface metal layer 32 overlying the polysilicon layer; a metal nitride layer 34 overlying the interface metal layer 32; and a conductor metal layer 36 overlying metal nitride layer 34. An insulating layer 38, such as silicon nitride, may cover the polysilicon layer 30. Polysilicon layer 30 desirably is about 20 to about 200 nanometers thick, although thicker or thinner polysilicon layers may be employed. Polysilicon layer 30 of this particular structure is n+ doped; other silicon-containing conductive layers can include p+ doped polysilicon or a doped polysilicon layer covered with a metal silicide (e.g., WSi, CoSi, NiSi). The polysilicon layer or other silicon-containing conductive layers may be formed by conventional processes such as various versions of chemical vapor deposition (CVD) including but not limited to low pressure CVD (LPCVD), ultra high vacuum CVD (UHV CVD), atomic layer or pulsed CVD (ALCVD), rapid thermal CVD (RTCVD), plasma enhanced or assisted CVD (PECVD), remote plasma CVD, metal-organic CVD (MOCVD), jet vapor CVD, as well as physical vapor deposition (PVD) or sputtering, and molecular beam deposition. The polysilicon dopants can be introduced during a deposition process via dopant precursor gas (e.g., AsH₃, PH₃, B₂H₆) or after formation of the polysilicon layer via ion implantation or gas phase doping.

After formation of the polysilicon or other silicon-containing conductive layer 30, interface metal layer 32 is applied. Preferably, prior to the application of the interface metal, the surface of the layer 30 is cleaned to remove native oxide that is formed, so that the surface of the layer is substantially free of native oxide, that is, the thickness of any remaining SiOₓ, or SiOₓN_{y} is less than about 10-14 Å. Native oxide may be removed from a polysilicon surface by techniques such as a wet clean, by baking the substrate in a reducing ambient, or by exposure to a plasma to sputter away the oxide. A preferred wet clean is performed using a diluted hydrofluoric acid (DHF) solution at a dilution ratio of water to HF of about 200:1 by molar fraction, preferably from about 200 to 400 seconds, more preferably for about 360 seconds. The HF-based solution may optionally contain various additives to passivate the silicon surface with a non-oxidizing species. Removal of native oxide by baking in a reducing ambient may be performed by exposure to pure hydrogen gas or a mixture of hydrogen gas and a neutral gas (e.g., nitrogen, argon), for example, at a temperature of about 900° C. for about one minute. Removal of native oxide by plasma exposure may be performed in an ion energy range of about 50 eV to 1000 eV, for example, using an argon-based plasma. A minimal plasma ion density of 10⁹ cm⁻³ in the vicinity of the substrate is required to complete the process within a reasonable time of about 10 minutes. Plasma treatment is preferably conducted in the same deposition chamber used to perform deposition of layer 32 to minimize wafer exposure to an oxidizing ambient after cleaning. Alternatively, the cleaned wafer is preferably transferred to the deposition chamber under a non-oxidizing reduced pressure (less than about 10 Torr) ambient.

Preferably, the interface metal of layer 32 as deposited contains little or no nitrogen. That is, the mole fraction of nitrogen in interface metal layer 32 is less than about 25% and most desirably as close to zero as is practicable. The interface metal is preferably highly reactive with respect to nonmetallic elements, such as oxygen or nitrogen. Examples of suitable highly reactive metals are transition metals such as Ti, Zr, Hf, Ta, La and alloys thereof. Most preferably, the interface metal is Ti. The interface metal may be deposited by essentially any conventional process that does not contaminate the structure, such as chemical vapor deposition (CVD), atomic layer deposition, or, more preferably, by physical vapor deposition (PVD) or sputtering from a metallic target in an argon or other inert gas atmosphere, which desirably is substantially free of nitrogen. The most preferred interface metal is titanium, and the as-deposited interface metal layer most desirably consists essentially of titanium. The interface metal layer as deposited desirably is less than 10 nm thick and more preferably about 0.25 to 2.5 nm thick, and most preferably about 1 nm thick. For example, sputtering using an apparatus of the type sold under the designation “Endura 5500” for a few seconds can form a satisfactory layer. The thickness of the deposited interface metal layer 32 is controlled via deposition time. An ultra thin layer of the interface metal may be deposited at power in the range from about 1 to about 5 kW, using deposition time from about 1 to about 30 sec, more preferably less than about 10 seconds, at Ar ambient pressure below about 10 mTorr. For example, a Ti film deposited at 1 kW power for about 5 seconds has a projected thickness of about 5 Å (or just about one or two monolayers). The interface metal as deposited may be continuous or discontinuous. However, if the interface metal layer 32 is discontinuous, the largest distance between two adjacent metal islands should not exceed the length of the smallest transistor gate. Present state-of-the-art transistors have a gate length of about 100 nm or less, which limits the characteristic size of interface metal layer discontinuities to below about 0.1 μm. Structure 12 desirably is maintained at a temperature of about 20° C. to about 400° C., more preferably 20° C. to about 150° C., during this deposition process.

The amount of deposited interfacial metal can be measured and monitored in terms of average surface density of interfacial metal atoms over a relatively large test site of about several square microns or larger. The standard Total reflection X-ray Fluorescence (TXRF) measurement technique is suitable for determining such average surface density of deposited interfacial metal atoms when the thickness of interfacial metal layer is less than about 1.0 nm. In the case of Ti interfacial metal, a Ti thickness of about 0.25 nm corresponds to the average Ti atom surface density of about 5e14 atoms/cm² while a Ti thickness of about 0.5 nm corresponds to the average Ti atom surface density of about 9.0e14 atoms/cm². Standard thickness measurement techniques such X-ray Fluorescence (XRF) and UV reflectivity can also be employed in measuring as-deposited interfacial metal layers. They are particularly suitable for layers thicker than about 0.7 nm.

After deposition of interface metal layer 32, a conductive, nitride-based layer 34 is deposited using techniques known in the art, such as CVD or PVD sputtering, and preferably conducted in the same tool to eliminate exposure to air. Preferably, the nitride-based layer 34 is deposited directly on the interface metal layer 32. Metal nitride layer 34 desirably is about 1-24 nm thick and more preferably about 4-16 nm thick, and most preferably about 4-10 nm thick. Metal nitride layers between 4-24 nm thick, and about 12-20 nm thick, such as about 16 nm thick also may be used. Metal nitrides thinner than about 4 nm adversely affect the overall barrier stability, while nitride layers thicker than about 16 nm do not substantially alter the barrier strength while undesirably increasing the height and aspect ratio of the conductive (e.g., gate) stack. As used in this disclosure, the term “metal nitrides” refers to compounds of one or more metals and nitrogen, and also includes compounds of one or more metals, silicon and nitrogen. The term “pure metal nitride” as used in this disclosure refers to compounds of one or more metals and nitrogen, without appreciable amounts of silicon. The term “binary pure metal nitride” means a pure metal nitride consisting essentially of one metal and nitrogen. The term “silicon-containing metal nitride” means a metal nitride that contains appreciable amounts of silicon as well as one or more metals and nitrogen. The metal nitride layer 34 may be a pure metal nitride such as WN, TaN, TiN or HfN, or a silicon-containing metal nitride such as WSiN, TaSiN, TiSiN or HfSiN. The metal nitride need not be exactly stoichiometric; it desirably has an atomic ratio of nitrogen to other constituents of about 0.3:1 to 1.5:1. Most preferably, the metal nitride layer consists essentially a stoichiometric or non-stoichiometric tungsten nitride. Tungsten nitride can be deposited by any suitable process, most preferably by sputtering from a tungsten target in an argon and nitrogen atmosphere. Desirably, the unitary structure 12 is maintained at a temperature of about 20° C. to about 400° C., and more preferably about 20° C. to about 150° C., during deposition of the metal nitride layer.

Conductor metal layer 36 may be of any thickness required to provide the desired conductivity in the structure and desired unit length capacitance of the structure, but most commonly is between about 10 and about 100 nm thick, for example, about 40 nm thick. Preferably, the conductor metal is a metal having a melting temperature above 1000° C. and most preferably above 2000° C. The conductor metal layer may include an alloy or a plurality of layers having different compositions, but most desirably is formed as a single layer of a single metal. The conductor metal is preferably a metal selected from the group consisting of W, Mo, Co, Ta, Nb, Re, Ir, Ni and combinations and alloys thereof, more preferably an elemental metal, such as W, Mo, Co, Ta, Nb, Re, fIr, or Ni. Most preferably, the conductor metal layer consists essentially of tungsten. Tungsten can be deposited by any suitable process, most preferably by sputtering from a tungsten target in an atmosphere of argon or other inert gas. The structure desirably is maintained at a temperature of about 20° C. to about 400° C., more preferably about 20° C. to about 150° C., during deposition of the tungsten.

Typically, the polysilicon, interface metal, metal nitride and conductive metal layers are deposited over the entire surface of the structure and then etched to leave these layers only in locations where the conductive element 10 is to be formed. Of course, multiple conductive elements can be formed simultaneously. For example, the interface metal, metal nitride and conductor metal layer of conductive element 24 are deposited simultaneously with the corresponding layers of conductive element 10.

After deposition of the layers forming the conductive element, the conductive elements may be covered with a layer of an insulating material such as silicon nitride 38. Additional structures (not shown) forming parts of the unitary integrated circuit 12 may be grown and processed by conventional techniques. These techniques may include high temperature processing steps, for example, processing at a temperature above about 800° C., typically between about 900° C. to 1,100° C., and most typically about 1,000° C. for relatively brief periods, typically less than a minute, and most desirably about 20 seconds. During such processing, during deposition of the metal nitride layer 34, or during deposition of the insulating nitride layer 38, or during all these steps, a nitrogen rich interfacial region 40 develops at the interface between interface metal layer 32 and polysilicon layer 30. This interfacial region contains silicon nitrogen compounds such as silicon nitride (e.g., SiNₓ), and has a preferred thickness of less than about 15 Å, more preferably between about 5 Å and about 10 Å. Although not preferred, the interfacial region may include a silicon oxynitride (e.g., SiOₓN_{y}), for example, if native oxide was present on the surface of the silicon-containing layer.

During high temperature processing, during deposition of the metal nitride layer 34, or during deposition of the insulating nitride layer 38, or during all these steps, interface metal layer 32 also is enriched in nitrogen. Some or all of the metal in layer 32 is converted to the corresponding nitride or oxynitride. Although the present invention is not limited by any theory of operation, it is believed that formation of the interface metal nitride or oxynitride in layer 32 competes with formation of silicon nitride or oxynitride in interfacial region 40, so that the presence of the interface metal layer limits the amount of silicon nitride or oxynitride formed in the interfacial region. However, sufficient silicon nitrogen compounds are formed in the interfacial region to substantially retard diffusion of metal from the conductor metal, metal nitride and interface metal layers or silicon from the silicon-containing layer 30 into the conductor metal layer 36, or retard diffusion of silicon from silicon-containing layer 30 into conductor metal layer 36 and thereby substantially suppress formation of metal suicides in silicon-containing layer 30 or conductor metal layer 36. Thus, after high temperature processing, the metal nitride layer 34, the interface metal layer 32 and the interfacial region 40 together form a barrier having sufficient thickness to effectively block diffusion and intermixing between the conductor metal layer 36 and the silicon-containing layer 30, but has a low interface resistance, desirably less than about 500 Ω-m². The total thickness of the barrier, consisting of the interfacial region 40, the interface metal layer 32 and the metal nitride layer 34, is preferably in the range from about 10 Å to about 200 Å, and more preferably in the range from about 25 Å to about 200 Å. Titanium is highly reactive with nitrogen and oxygen to form titanium nitride or titanium oxynitride. Stated another way, the free energy of formation of titanium nitride is about 338 kJ/mol which is substantially higher than the free energy of formation of silicon nitride (about 248 kJ/mol). As a result, active nitrogen preferentially reacts with titanium. It is believed that other metals, which are similarly reactive with nitrogen to form electrically conductive metal nitrides, and which are otherwise capable of withstanding high-temperature processing can be employed as the interface metal in place of titanium. For example, the free energy of formation of tantalum nitride is about 252 kJ/mol, and it is therefore believed that tantalum or other highly reactive transition metals can be employed in place of titanium. Typical highly reactive transition metals have fewer than 5 d-electrons on the outer shell, as opposed to noble transition metals with more than 6 d-electrons on the outer shell. It is believed that highly reactive transitional metals that may be used for the interface metal of the present invention include Ti, Zr, Hf, Ta, La and alloys thereof. The most highly reactive transitional metals are those with 2 d-electrons on the outer shell, such as Ti, Zr, or Hf.

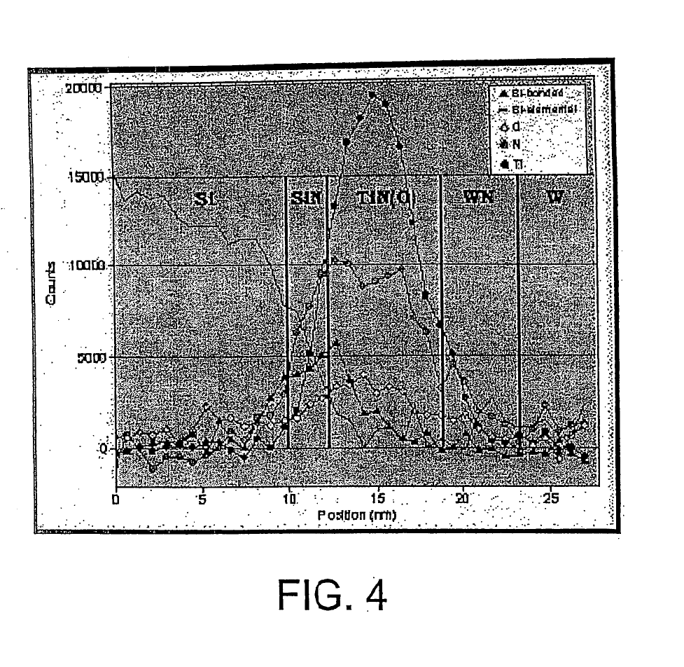

One example of a final silicidation barrier structure (after all high-temperature anneal(s) and deposition steps) was experimentally studied with a high resolution tunneling electron microscope (TEM) and Electron Energy Loss Spectroscopy (EELS) technique. Typical EELS spectrum of a polySi/Ti/WN/W stack, annealed at a temperature of about 950° C., for about 60 seconds, is shown in FIG. 4. Referring to FIG. 4, the barrier includes (a) an ultra-thin interfacial region 40 comprised of semi-insulating silicon-nitrogen and silicon-oxygen compounds such as SiOₓN_{y} (SiN(O)) of less than about 15 Å; (b) an thin conductive layer with interfacial Ti metal 32 comprising primarily titanium oxynitride TiOₓN_{y} with a low concentration of oxygen TiN(O); and (c) a partially decomposed tungsten nitride WN layer 34. Note that WN decomposes at temperatures above about 800° C. (much lower than the temperature of the anneal); nevertheless, a thin WN layer (˜10 Å) is still present in the final structure. The spatial resolution of the EELS measurement technique as judged by the characteristic electron beam size is about 5 Å. Without intending to limit the present invention, it is believed that the interfacial Ti metal layer 32 prevents formation of a thick semi-insulating layer during deposition of the metal nitride-based conductive barrier 34 and during decomposition or reaction with silicon of such a nitride-based barrier at high-temperature.

The thermal stability of an annealed gate stack of polySi/Ti/WN/W, formed in accordance with one embodiment of the invention, was evaluated in a set of experiments where the stack was heated in a rapid thermal processor at a specified temperature and for a specified time. The appearance of gate electrode voids, believed to be formed at the onset of silicidation of the gate conductor, are earmarks of the loss of thermal stability. The voids were monitored via scanning electron microscope (SEM) micrographs and the thermal stability limit (temperature and time) was determined for each barrier at the onset of void formation. An alternative determination of thermal stability was obtained by measuring the sheet resistance Rₛ of the annealed gate stack (substrate/polysilicon/barrier/tungsten) using a standard 4-point probe measurement at 49 locations within the wafers. Mean value of the sheet resistance Rₛ of the gate stack, standard deviation of Rₛ (1 sigma), minimal Rₛ value R_{s,min} and maximum Rₛ value R_{s,max} were determined for each anneal temperature and time. The loss of thermal stability of the barrier manifests itself as a sudden increase of Rₛ, max and standard variation (1 sigma). It has been found that the SEM-based technique is slightly more sensitive than the sheet resistance technique but, nevertheless, the results of the sheet resistance technique agree well with that of the SEM technique.

The thermal stability of a Ti-containing barrier as a function of both nitrogen content in the WN film and of thickness of the WN film has been investigated. The nitrogen content in WN film was adjusted by varying the flow ratio between nitrogen gas and argon gas delivered into the deposition chamber. A high nitrogen content WN film was deposited with an argon to nitrogen gas flow ratio of 2:11. Correspondingly, a low nitrogen content WN film was deposited using an argon to nitrogen gas flow ratio of 4:5. The low nitrogen WN film had the stoichiometry of about WN_{0.6} while the high nitrogen WN had a stoichiometry of aboutWN_{1.6}, both in as deposited form. Two low nitrogen content WN films having thicknesses of 8 nm and 16 nm were formed, and a high nitrogen content WN film was formed having a thickness of about 4 nm. A 40 nm tungsten film was deposited on top of the WN films in the same deposition system (without breaking vacuum). The stacks were then subjected to various high-temperature anneals. The results of Rₛ measurements are summarized in Table I, below. Table I shows the anneal temperature and time dependence of stack sheet resistance and related parameters for three different WN films: (1) 4 nm thick, high N content; (2) 8 nm thick, low N content in; and (3) 16 nm thick, low N content in.

TABLE I

| | | | |
|---|---|---|---|
| Rs, mean | 1 sigma, | % Rs, min | Rs, max |

Low Nitrogen Content, 16 nm

| | | | | |
|---|---|---|---|---|
| As deposited | 9.87-10.50 | 2.05-2.32 | 9.66-10.29 | 10.60-11.20 |
| 950 C., 60 sec | 3.78-3.83 | 1.77-2.40 | 3.66-3.70 | 3.94-4.01 |
| 1000 C., 60 sec | 3.9 | 5.46 | 3.56 | 4.42 |
| 1000 C., 120 sec | 3.69 | 8.12 | 3.29 | 4.29 |
| 1025 C., 30 sec | 3.84 | 7.21 | 3.32 | 4.39 |
| 1050 C., 30 sec | 4.54 | 23.31 | 3.36 | 7.61 |

Low Nitrogen Content, 8 nm

| | | | | |
|---|---|---|---|---|
| As deposited | 11.39-11.45 | 2.09-2.12 | 11.13-11.22 | 12.16-12.22 |
| 950 C., 60 sec | 4.84-4.89 | 1.73-3.19 | 4.66-4.72 | 5.01-5.17 |
| 1000 C., 60 sec | 4.96 | 6.09 | 4.57 | 5.94 |
| 1000 C., 120 sec | 4.58 | 8.57 | 3.97 | 5.49 |
| 1025 C., 30 sec | 4.75 | 6.71 | 4.14 | 5.36 |
| 1050 C., 30 sec | 5.78 | 26.14 | 4.24 | 10.11 |

High Nitrogen Content, 4 nm

| | | | | |
|---|---|---|---|---|
| As deposited | 13.33-13.40 | 2.03-2.08 | 13.06-13.45 | 14.19-14.25 |
| 950 C., 60 sec | 5.83-6.00 | 2.41-4.58 | 5.48-5.58 | 6.08-6.47 |
| 1000 C., 60 sec | 5.51 | 3.81 | 5.25 | 6.18 |
| 1000 C., 120 sec | 5.04 | 2.21 | 4.83 | 5.29 |
| 1025 C., 30 sec | 5.32 | 3.17 | 5.09 | 5.92 |
| 1050 C., 30 sec | 5.34 | 14.99 | 4.84 | 8.57 |

The stacks with low N content WN films show signs of silicidation when annealed at 1000° C. for 60 seconds, because both Rₛ, max and standard deviation increases at this anneal condition. The stack with the 4 nm thick, high N content WN film starts losing its thermal stability at the 1025° C., 30 second anneal while showing no signs of stability loss at 1000° C., 120 seconds. All investigated stacks are apparently stable at the 950° C., 60 second anneal.

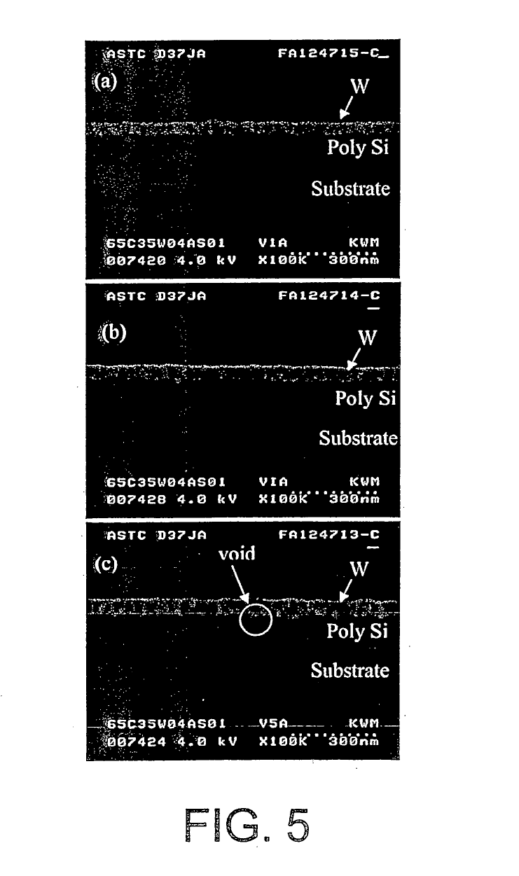

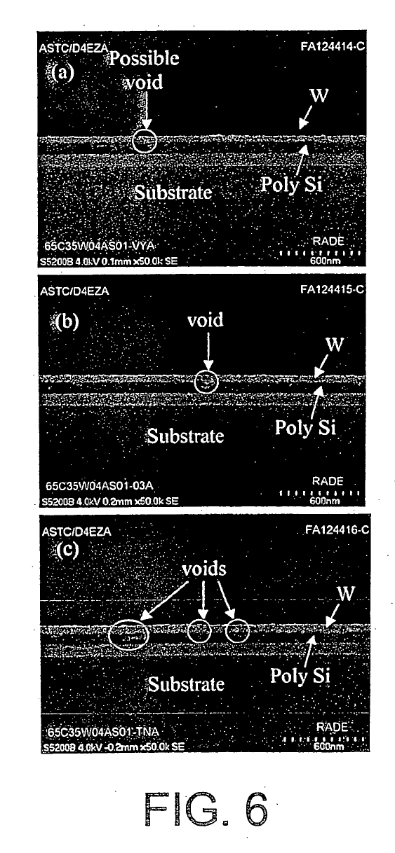

The results of SEM-based stability experiments are summarized in FIGS. 5 and 6. FIG. 5 shows micrographs of the same three stacks with different WN layers all subjected to a 1000° C., 20 second anneal. While the stacks with 4 nm thick, high N content WN film (FIG. 5a) and 8 nm thick, low N content WN film (FIG. 5b) showed no signs of barrier stability loss, the 16 nm thick, low N content WN film (FIG. 5c) showed clear Si voids, which are earmarks of the local barrier stability loss and beginning of tungsten silicidation. FIG. 6 shows micrographs of the same three stacks with different WN layers all subjected to a 1000° C., 60 second anneal. While the stack with the 4 nm thick, high N content WN film (FIG. 6a) showed marginal barrier stability, the stacks with both 8 nm thick, low N content film (FIG. 6b) and the 16 nm thick, low N content WN film (FIG. 6c) showed clear Si voids, which are earmarks of local barrier stability loss and beginning of tungsten silicidation.

Based on the described thermal stability experiments, it was concluded that the barrier with high N content WN film had a slightly better stability than the stacks with low N content WN film. In addition, it was concluded that the increase of WN layer thickness from 8 nm to 16 nm does not result in any measurable improvement of the barrier stability. Therefore, it was determined that the preferred thickness of the WN film is from about 2 nm to about 10 nm while the preferred composition of WNₓ is where x is between 1 and 2.

The high temperature processing step also serves to anneal the other elements of the structure and to reduce the resistivity of the structure. For example, a structure incorporating a 1 nm titanium interface metal layer, a 16 nm tungsten nitride layer and a 40 nm tungsten conductor metal layer has a sheet resistance of about 10 ohms per square as deposited and about 4 to about 5 ohms per square after high temperature processing. The same structure has an interface resistance of about 70 Ω-μm² after high temperature processing. By contrast, a comparable structure without the titanium layer has an interface resistivity of about 5,000-10,000 Ω-μm² after high temperature processing.

A further advantage of structures according to preferred embodiments of the present invention is that such structures including the titanium interfacial metal are substantially stable when exposed to an oxidizing gas mixture of water vapor and hydrogen as, for example, exposure to such a mixture with respective relative mole fractions of 10% and 90% at an elevated temperature of above about 900° C. and less than about 1050° C. for a period of less than 180 seconds. Under these conditions, titanium containing materials such as Ti, TiN, TiSix, and the like typically react with the oxidizing agent resulting in the fast destruction of the barrier. Although the present invention is not limited by any theory of operation, it is believed that the ultra-thin nature of the layer containing the interfacial metal as discussed above contributes to this stability. Thus, if the structure is etched or otherwise processed to form features such as elongated conductors after deposition of the various layers, edges of the individual layers will be exposed at the edges of the features. The layer containing the interfacial metal is protected by the overlying conductor metal and nitride layers except at the edges. Thus, oxidation of a titanium interfacial metal would be expected to proceed laterally from the exposed edges. The rate of any lateral oxidation is substantially reduced in an extremely thin interfacial metal layer (e.g., 2.5-25 Angstroms) yielding oxidation resistant property of the barrier.

Numerous variations and combinations of the features described above can be utilized without departing from the present invention. For example, metals other than tungsten can be used as the conductor metal and as constituents of the metal nitride layer. For example, molybdenum or chromium can be used. The nitride layer can be a nitride of the interface metal layer, for example, a layer of titanium nitride where the interface metal is titanium. In another alternative, the nitride layer can be a nitride of a metal or metals different from the interface metal and different from the conductor metal layer, for example, a nitride layer of tantalum silicon nitride used with an interface layer of titanium and a conductor metal layer of tungsten. Further, although the various layers are discussed separately above, it is not essential to provide sharp transitions between the layers. For example, the nitride layer and conductor metal layer may be deposited as parts of a larger layer having progressively decreasing nitrogen content, so that the first-deposited portion of the layer, nearest to the interface metal layer, has a relatively high nitrogen content as discussed above in connection with the nitride layer, whereas the last-deposited portion contains little or no nitrogen. Also, the conductive structures discussed above can be employed in any monolithic microelectronic device.

As these and other variations and combinations of the features discussed above can be used without departing from the present invention, the foregoing description of the preferred embodiments should be taken by way of illustration rather than by way of limitation of the invention. The appended claims further define certain features of the invention.

### INDUSTRIAL APPLICABILITY

The present invention is applicable to the manufacturing of conductive structures used in semiconductor devices, and more particularly relates to methods of creating and manufacturing integrated circuits for use in the production of electronics components.

What is claimed is:

1. A method of forming a conductive structure, the method comprising:
depositing a layer including an interface metal over a silicon-containing electrically conductive layer;
depositing a layer including an electrically conductive metal nitride over said interface metal; and
depositing a layer of a conductor metal over said nitride.

2. The method as claimed in claim 1 wherein said silicon-containing electrically conductive layer includes polysilicon.

3. The method as claimed in claim 2 wherein said interface metal layer is deposited directly on said polysilicon.

4. The method as claimed in claim 1 wherein said interface metal includes titanium.

5. The method as claimed in claim 4 wherein said step of depositing said layer including a interface metal is performed by depositing titanium directly on said silicon-containing layer.

6. The method as claimed in claim 5 wherein said step of depositing said layer including a metal nitride is performed by depositing said nitride directly on said titanium and said step of depositing said conductor metal is performed by depositing said conductor metal directly on said nitride.

7. The method as claimed in claim 6 wherein said nitride is a pure metal nitride.

8. The method as claimed in claim 6 wherein said nitride includes tungsten nitride and said conductor metal includes tungsten.

9. The method as claimed in claim 6 wherein said nitride is a silicon-containing metal nitride.

10. The method as claimed in claim 8 further comprising annealing the structure after said depositing steps.

11. The method as claimed in claim 1 further comprising annealing the structure after said depositing steps.

12. The method as claimed in claim 11 wherein said annealing step includes further processing the structure at a temperature above 800° C. after said depositing steps.

13. The method as claimed in claim 5 wherein said step of depositing titanium is performed so as to deposit said titanium to a thickness between 0.25 and 10 nm.

14. The method as claimed in claim 9 wherein said step of depositing titanium is performed so as to deposit said titanium to a thickness between 0.25 and 10 nm.

15. The method as claimed in claim 14 wherein said step of depositing said nitride is performed so as to deposit said nitride to a thickness of at least 4 nm.

16. The method as claimed in claim 15 wherein said step of depositing said nitride is performed so as to deposit said nitride to a thickness of at least 8 nm.

17. A structure formed by a process as claimed in claim 10.

18. A structure formed by a process as claimed in claim 15.

19. A conductive structure comprising:
a silicon-containing electrically conductive layer;
a layer including an interface metal overlying said silicon-containing layer;
a layer including an electrically conductive metal nitride overlying said layer including a interface metal; and
a layer including a conductor metal overlying said nitride layer.

20. The structure as claimed in claim 19 wherein said silicon-containing layer includes polysilicon.

21. The structure as claimed in claim 20 wherein said silicon-containing layer consists essentially of polysilicon.

22. The structure as claimed in claim 19 wherein said interface metal comprises at least one metal selected from the group consisting of Ti, Zr, Hf, Ta, La and alloys thereof.

23. The structure as claimed in claim 21 wherein said interface metal includes titanium.

24. The structure as claimed in claim 23 wherein said metal nitride includes tungsten nitride and said conductor metal includes tungsten.

25. The structure as claimed in claim 19 wherein said layer including an interface metal is between 0.25 and 2.5 nm thick.

26. The structure as claimed in claim 25 wherein said layer including an interface metal is between 0.25 and 1 nm thick.

27. The structure as claimed in claim 25 wherein said nitride layer is between 4 nm and 24 nm thick.

28. The structure as claimed in claim 19 wherein said conductor metal has a melting temperature of above 1000° C.

29. The structure as claimed in claim 19 wherein said conductor metal comprises at least one metal selected from the group consisting of W, Mo, Co, Ta, Nb, Re, fIr, Ni and combinations and alloys thereof.

30. The structure as claimed in claim 19 wherein said nitride layer includes a pure metal nitride.

31. The structure as claimed in claim 19 wherein said nitride layer includes a silicon-containing metal nitride.

32. The structure as claimed in claim 19 wherein said silicon-containing layer includes a region adjacent said interface metal layer enriched in nitrogen relative to the remainder of said silicon-containing layer.

33. The structure as claimed in claim 32 wherein said region adjacent said interface metal layer enriched in nitrogen has a thickness between about 5 Å and about 15 Å.

34. The structure as claimed in claim 19 further comprising an oxide layer underlying said silicon-containing layer.

35. The structure as claimed in claim 19 having an interfacial resistance between said conductor metal layer and said silicon-containing layer of 500 Ω-μm² or less.

36. An integrated circuit including a structure as claimed in claim 19.
